(19) United States
(12) Patent Application Publication
(10) Pub. No.: US 2026/0135465 A1
(43) Pub. Date: May 14, 2026

(54) GATE DRIVING SYSTEM

(71) Applicant: Renesas Design (UK) Limited, Bourne End (GB)

(72) Inventors: Jung Woo CHOI, Pleasanton, CA (US); Chuanyang WANG, San Jose, CA (US); Kai WAN, San Jose, CA (US); Guang FENG, San Jose, CA (US)

(73) Assignee: Renesas Design (UK) Limited, Bourne End (GB)

(21) Appl. No.: 18/947,204

(22) Filed: Nov. 14, 2024

(51) Int. Cl. H02M 1/08; H02M 3/158; H03K 17/687

(52) U.S. Cl. CPC H02M 1/08; H02M 3/158; H03K 17/687

(57) ABSTRACT

A gate driving system for driving a switching operation of a first switch, the gate driving system being configured to receive a control signal, provide a gate drive voltage signal to a gate terminal of the first switch to drive the switching operation of the first switch, detect a first voltage at a first terminal of the first switch, and adjust the gate drive voltage signal based on the first voltage, as detected.

### FIELD

The present disclosure relates to a gate driving system. In particular, the present disclosure relates to a gate driving system for driving a switching operation of a switch.

### BACKGROUND

Switches, such as power switches, are ubiquitous in electronic circuits. The opening and closing of the switches may be controlled by a gate drive voltage being applied to a terminal of the switch. A switch may be provided by a transistor such as a metal-oxide-semiconductor field-effect-transistor (MOSFET).

Selecting the correct drive voltage for a MOSFET is crucial, as it directly impacts circuit functionality, safety, and overall performance. The optimal drive voltage depends on several factors such as: the type of MOSFET, its threshold voltage, the application's requirements, the balance between switching speed related EMI and power loss, and the capabilities of the gate drive circuitry.

The chosen drive voltage preferably remain within the MOSFET's rated parameters such as its maximum Gate Voltage Limit (V_{gs_max}), while meeting the performance demands of the application.

### SUMMARY

It is desirable to provide an improved gate driving system for driving a switching operation of a switch.

According to a first aspect of the disclosure there is provided a gate driving system for driving a switching operation of a first switch, the gate driving system being configured to receive a control signal, provide a gate drive voltage signal to a gate terminal of the first switch to drive the switching operation of the first switch, detect a first voltage at a first terminal of the first switch, and adjust the gate drive voltage signal based on the first voltage, as detected.

Optionally, the gate driving system is configured to provide the gate drive voltage signal having a first gate drive voltage when the control signal is in a first state, and provide the gate drive voltage signal having a second gate drive voltage when the control signal is in a second state.

Optionally, the gate driving system is configured to adjust the first gate drive voltage using the first voltage as detected, to maintain a substantially constant difference between the first gate drive voltage and the first voltage whilst the control signal is in the first state, and/or adjust the second gate drive voltage using the first voltage as detected, to maintain a substantially constant difference between the second gate drive voltage and the first voltage whilst the control signal is in the second state.

Optionally, the first switch is a metal-oxide-semiconductor field-effect transistor (MOSFET).

Optionally, the first switch is an insulated-gate bipolar transistor (IGBT).

Optionally, the MOSFET is a silicon MOSFET, a silicon carbide MOSFET or a gallium nitride MOSFET.

Optionally, the MOSFET is an N-channel enhancement-mode MOSFET.

Optionally, the first voltage is a source voltage and the first terminal is a source terminal.

Optionally, the first switch is coupled to a sense resistor at the first terminal and/or the first switch is coupled to additional circuitry at a second terminal.

Optionally, the control signal is a pulse width modulation (PWM) signal.

Optionally, the gate driving system comprises a gate driver circuit configured to receive the control signal, and provide the gate drive voltage signal to the gate terminal of the first switch to drive the switching operation of the first switch, and a compensation circuit configured to detect the first voltage at the first terminal of the first switch, and provide an adjustment signal that is dependent on the detected first voltage to the gate driver circuit, wherein the gate driver circuit is configured to adjust the gate drive voltage signal based on the received adjustment signal.

Optionally, the compensation circuit is configured to receive a supply voltage, and generate an adjusted supply voltage based on the detected first voltage, the adjustment signal being dependent on the adjusted supply voltage.

Optionally, the adjustment signal is the adjusted supply voltage.

Optionally, the gate driving system is configured to provide the gate drive voltage signal having a first gate drive voltage when the control signal is in a first state, provide the gate drive voltage signal having a second gate drive voltage when the control signal is in a second state, and providing the first gate drive voltage using adjusted supply voltage, thereby adjusting gate drive voltage signal based on the first voltage, and/or the second gate drive voltage using adjusted supply voltage, thereby adjusting gate drive voltage signal based on the first voltage

Optionally, the compensation circuit comprises an addition circuit configured to generate the adjusted supply voltage by adding the supply voltage and the detected first voltage.

Optionally, the addition circuit is configured to successively generate the adjusted supply voltage at discrete time intervals during operation.

According to a second aspect of the disclosure there is provided an apparatus comprising a controller for controlling a power converter for receiving an input voltage and generating an output voltage, the power converter comprising one or more power switches, wherein the controller comprises a gate driving system for driving a switching operation of each of the one or more power switches, the gate driving system being configured to receive a control signal, and for each of the one or more power switches provide a gate drive voltage signal to a gate terminal of the power switch to drive the switching operation of the power switch, detect a first voltage at a first terminal of the power switch, and adjust the gate drive voltage signal based on the first voltage, as detected.

Optionally, the apparatus comprises the power converter.

Optionally, the controller is configured to provide a discontinuous conduction mode (DCM) or a continuous conduction mode (CCM) for the power converter

Optionally, the power converter is a buck converter, a boost converter or a buck-boost converter.

Optionally, the power converter is a buck based converter, a boost based converter or a buck-boost based converter, such as flyback, forward, Cuk converter etc. Optionally, the source of the power switch is connected to the ground via a device with impedance, such as a sensing resistor

It will be appreciated that the apparatus of the second aspect may include features set out in the first aspect and can incorporate other features as described herein.

According to a third aspect of the disclosure there is provided a method of driving a switching operation of a first switch using a gate driving system comprising receiving a control signal, providing a gate drive voltage signal to a gate terminal of the first switch to drive the switching operation of the first switch, detecting a first voltage at a first terminal of the first switch, and adjusting the gate drive voltage signal based on the first voltage, as detected.

It will be appreciated that the method of the third aspect may include using and/or providing features set out in the first aspect and/or second aspect, and can incorporate other features as described herein.

### BRIEF DESCRIPTION OF THE DRAWINGS

The disclosure is described in further detail below by way of example and with reference to the accompanying drawings, in which:

FIG. 1A is a graph showing the relationship between the gate source voltage and the drain-source on-resistance for an N-channel enhancement mode MOSFET, FIG. 1B is a graph showing the relationship between temperature and drain current for an N-channel enhancement mode MOSFET;

FIG. 2A is a schematic of an apparatus comprising a controller, FIG. 2B is a schematic of an apparatus comprising an isolated driver;

FIG. 3A is a graph showing the waveforms relating to the operation of a practical implementation of the apparatus of FIG. 2A operating in a discontinuous conduction mode (DCM), FIG. 3B is a graph showing the waveforms relating to the operation of a practical implementation of the apparatus of FIG. 2A operating in a continuous conduction mode (CCM), FIG. 3C is a graph showing the waveforms relating to the operation of a practical implementation of the apparatus of FIG. 2B operating in a discontinuous conduction mode (DCM), FIG. 3D is a graph showing the waveforms relating to the operation of a practical implementation of the apparatus of FIG. 2B operating in a continuous conduction mode (CCM);

FIG. 4A is a schematic of a gate driving system for driving a switching operation of a switch, in accordance with a first embodiment of the present disclosure, FIG. 4B is a schematic of a specific embodiment of the gate driving system of FIG. 4A in accordance with a second embodiment of the present disclosure, FIG. 4C is a graph showing waveforms associated with the operation of a practical implementation of the gate driving system of FIG. 4B;

FIG. 5A is a schematic of a specific embodiment of the gate driving system of FIG. 4A in accordance with a third embodiment of the present disclosure, FIG. 5B is a schematic of the gate driving system having a specific embodiment of the compensation circuit, in accordance with a fourth embodiment of the present disclosure, FIG. 5C is a schematic of the gate driving system having a specific embodiment of the compensation circuit, in accordance with a fifth embodiment of the present disclosure;

FIG. 6A is a graph showing waveforms associated with the operation of a practical implementation of the gate driving system of FIG. 5B, which is the linear adaptive MOSFET drive approach using DCM, FIG. 6B is a graph showing waveforms associated with the operation of a practical implementation of the gate driving system of FIG. 5B, which is the linear adaptive MOSFET drive approach using CCM, FIG. 6C is a graph showing waveforms associated with the operation of a practical implementation of the gate driving system of FIG. 5B, which is the non-linear adaptive MOSFET drive approach using DCM, FIG. 6D is a graph showing waveforms associated with the operation of a practical implementation of the gate driving system of FIG. 5B, which is the non-linear adaptive MOSFET drive approach using CCM; and

FIG. 7 is a schematic of an apparatus in accordance with a sixth embodiment of the present disclosure.

### DETAILED DESCRIPTION

Several parameters are considered in the selection of a drive voltage for a MOSFET.

The higher the drive voltage, the lower the drain-source on resistance R_{ds}_{ₒₙ}, the lower conduction loss, and lower switching loss because the MOSFET turn-on speed will be faster. However, a higher drive voltage will sacrifice electromagnetic interference (EMI) performance because of a faster turn-on and the MOSFET gate charging loss will be higher. Additionally, a margin must be maintained between the drive voltage and the maximum gate voltage limit V_{gs}_{ₘₐₓ} to ensure that, even in the worst-case scenarios—including oscillations of the gate voltage caused by parasitic inductance in the drive circuit—the drive voltage does not exceed the gate voltage limit V_{gs}_{ₘₐₓ}. By taking the above factors into account, designers can choose an appropriate drive voltage that ensures the MOSFET operates efficiently and reliably for the specific application. Embodiments of the present disclosures will primarily be presented for an N-channel enhancement-mode MOSFET. However, it will be appreciated that other switch types may be used for further embodiments in accordance with the understanding of the skilled person.

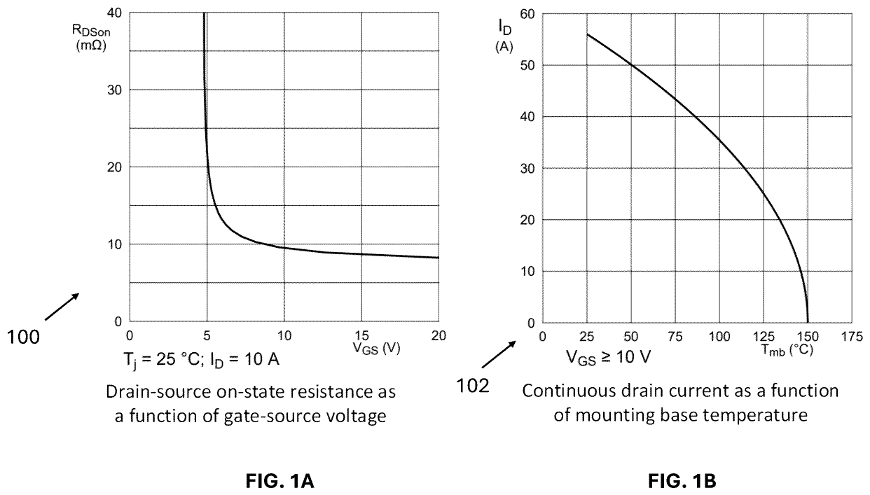

FIG. 1A is a graph 100 showing the relationship between the gate source voltage V_{GS} and the drain-source on-resistance R_{Dson} for an N-channel enhancement mode MOSFET. FIG. 1B is a graph 102 showing the relationship between temperature and drain current ID for an N-channel enhancement mode MOSFET.

As shown in FIG. 1A and FIG. 1B, the higher the gate source voltage V_{gs}, the lower the drain-source on-resistance R_{Dson}, which reduces conduction losses. This is especially important in high-current applications. If the gate source voltage V_{gs} is too low, the drain-source on-resistance R_{Dson}, increases, resulting in higher conduction losses, significant heating of the components, and reduced current-handling capability, potentially causing circuit malfunction.

In power converter design, measuring the current through a MOSFET is often necessary for current control or protection. To keep costs low, this is typically done using a sense resistor placed between the MOSFET's source and ground (GND). The power converter may, for example, be a boost converter.

Usually, there are two conventional gate driver control methods: non-isolated drive method and isolated drive method. The following sections will introduce each method, along with their respective advantages and disadvantages.

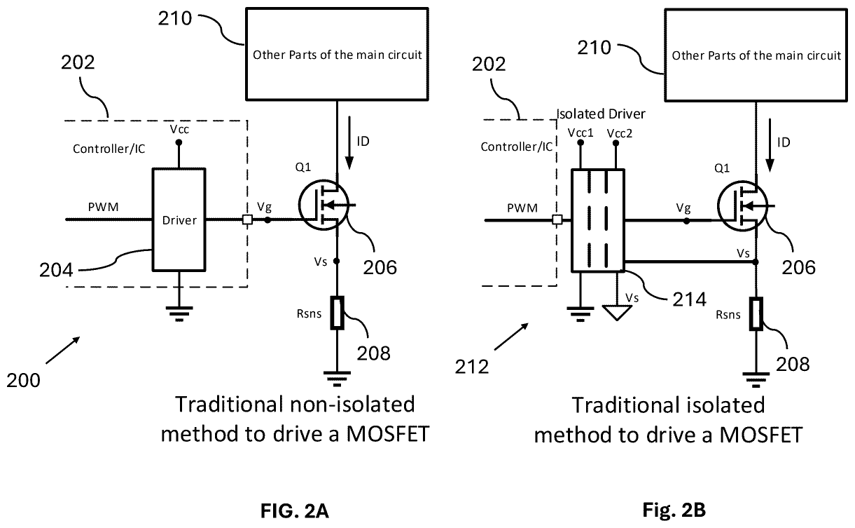

FIG. 2A is a schematic of an apparatus 200 comprising a controller 202 comprising a gate driver 204 for driving a MOSFET 206. The MOSFET 206 is coupled to a sense resistor 208 and additional circuitry 210. FIG. 2A shows a known non-isolated driving method. FIG. 2B is a schematic of an apparatus 212 comprising an isolated driver 214 for driving the MOSFET 206.

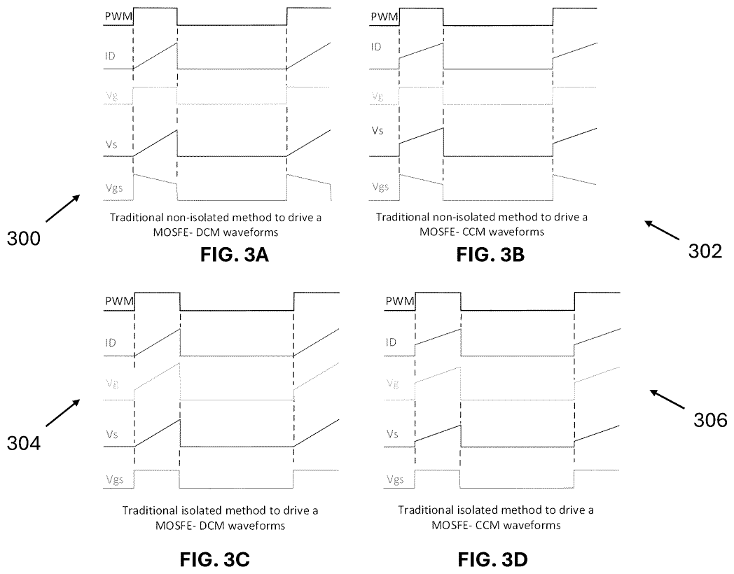

FIG. 3A is a graph 300 showing the waveforms relating to the operation of a practical implementation of the apparatus 200 operating in a discontinuous conduction mode (DCM). FIG. 3B is a graph 302 showing the waveforms relating to the operation of a practical implementation of the apparatus 200 operating in a continuous conduction mode (CCM).

FIG. 3C is a graph 304 showing the waveforms relating to the operation of a practical implementation of the apparatus 212 operating in a discontinuous conduction mode (DCM). FIG. 3D is a graph 306 showing the waveforms relating to the operation of a practical implementation of the apparatus 212 operating in a continuous conduction mode (CCM).

The conventional gate drive control method, a non-isolated solution to drive the MOSFET 206, as shown in FIG. 2A and the relevant waveform for this method is shown in FIG. 3A and FIG. 3B. This method sets the gate voltage to a fixed value optimized for efficiency, electromagnetic interference (EMI), and the MOSFET's V_{gs} rating.

However, as the current ID through the sense resistor 208 increases, the source voltage Vₛ of the MOSFET 206 also rises, which in turn reduces the gate-to-source voltage V_{gs}. As a result, the V_{gs} deviates from its optimized value, leading to an increase in R_{ds}_{ₒₙ}. This causes greater heat dissipation, reduces the MOSFET's current-handling capability, and, in severe cases, can lead to circuit failure.

A designer could compensate for the drop in V_{gs} voltage caused by an increase in MOSFET current ID by raising the gate voltage V_{g}. However, this approach would bring the V_{gs} voltage closer to its maximum value (V_{gs}_{ₘₐₓ}) when the MOSFET current ID is low, potentially leading to problems such as increased electromagnetic interference (EMI) and additional driving losses due to the rise in gate charge (Q_{gs}).

An alternative traditional approach, the isolated solution to drive the MOSFET 206, as shown in FIG. 2B, uses the isolated driver 214. The relevant waveforms for this method are shown in FIG. 3C and FIG. 3D. The reference ground of this isolated driver 214 is connected to the MOSFET's source Vₛ, ensuring that the V_{gs} remains stable regardless of changes in Vₛ. However, this method increases costs and requires additional wiring. Moreover, since isolated drivers are challenging to integrate into a chip, this method not only increases costs but also adds to the overall size of the final design.

In summary, while the traditional non-isolated method for driving a MOSFET is cost-effective, the gate-to-source voltage (V_{gs}) fluctuates with changes in the source voltage (Vₛ), deviating from its initially optimized value. As the current increases, the V_{gs} voltage drops, leading to a higher R_{ds}_{ₒₙ} which reduces efficiency and power density. The traditional isolated method, which uses an isolated driver, solves this issue but adds extra cost, complexity due to additional wiring, and size.

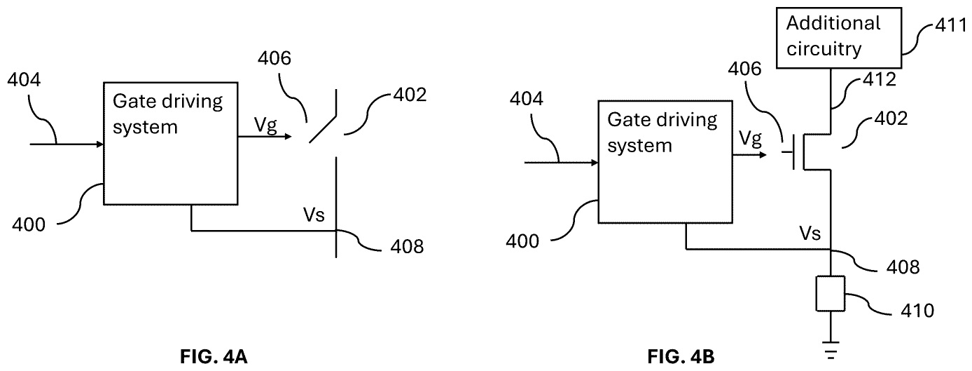

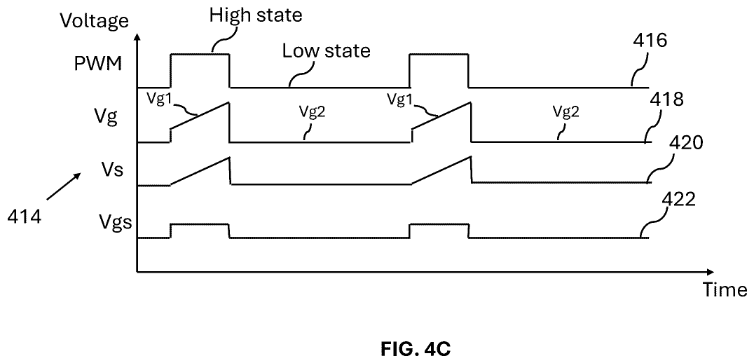

FIG. 4A is a schematic of a gate driving system 400 for driving a switching operation of a switch 402, in accordance with a first embodiment of the present disclosure.

The gate driving system 400 is configured to receive a control signal 404 and to provide a gate drive voltage signal Vg to a gate terminal 406 of the switch 402 to drive the switching operation of the switch 402. The control signal 404 may be a pulse width modulation (PWM) signal. The gate drive voltage signal Vg may be dependent on the control signal 404.

The gate driving system 400 is further configured to detect a voltage Vs at a terminal 408 of the switch 402, and to adjust the gate drive voltage signal Vg based on the voltage Vs, as detected.

FIG. 4B is a schematic of a specific embodiment of the gate driving system 400 of FIG. 4A in accordance with a second embodiment of the present disclosure. In the present embodiment, the switch 402 is a MOSFET. The MOSFET 402 may, for example, be a silicon MOSFET, a silicon carbide MOSFET or a gallium nitride MOSFET. The MOSFET 402 may, for example, be an N-channel enhancement-mode MOSFET. In the present embodiment, the voltage Vs is a source voltage and the terminal 408 is a source terminal. In a further embodiment, the switch 402 may be an insulated-gate bipolar transistor (IGBT).

In the present embodiment, the switch 402 is coupled to a sense resistor 410 at the terminal 408 and the switch 402 is coupled to additional circuitry 411 at a terminal 412.

FIG. 4C is a graph 414 showing waveforms associated with the operation of a practical implementation of the gate driving system 400 of FIG. 4B. In the present example, the waveforms are represented as voltages varying with time.

A trace 416 is the control signal 404. In the present embodiment the control signal is a PWM signal which is a digital signal that switches between a first state and a second state. In the present example, the first state is a high state and the second state is a low state. Examples of the high and low states are labelled in FIG. 4C.

A trace 418 is the gate drive voltage signal Vg. During operation, the gate driving system 400 sets the gate drive voltage signal Vg to a first gate drive voltage Vg1 when the control signal 404 is in the first state, being the high state, and sets the gate drive voltage signal Vg to a second gate drive voltage Vg2 when the control signal 404 is in the second state, being the low state.

When the gate drive voltage Vg1 is provided to the switch 402, the switch 402 may be in a closed state (which may be referred to as an “on” state), when current is permitted to flow through the switch 402. When the gate drive voltage Vg2 is provided to the switch 402, the switch may be in an open state (which may be referred to as an “off” state), when current is not permitted to flow through the switch 402.

In a further embodiment, the gate drive voltage Vg1 being provided to the switch 402 may set the switch 402 to an open state and the gate drive voltage Vg2 being provided to the switch 402 may set the switch 402 to a closed state.

In the present embodiment, the value of the first gate drive voltage Vg1 varies linearly. In further embodiments, the value of the first gate drive voltage Vg1 may vary non-linearly. In further embodiments, the value of the second gate drive voltage Vg2 may additionally, or alternatively, vary linearly or non-linearly.

A trace 420 shows the source voltage Vs as it varies with time and a trace 422 shows the gate-to-source voltage Vgs as it varies with time.

In the present embodiment, the gate driving system 400 is configured to adjust the gate drive voltage Vg1 using the voltage Vs as detected to maintain a substantially constant difference between the gate drive voltage Vg1 and the voltage Vs whilst the control signal 404 is in the first state (the high state). The difference between Vg1 and Vs is the gate-to-source voltage Vgs whilst the control signal 404 is in the first state (the high state).

In a further embodiment, additionally or alternatively, the gate drive system may be configured to adjust the gate drive voltage Vg2 using the voltage Vs as detected, to maintain a substantially constant difference between the gate drive voltage Vg2 and the voltage V2 whilst the control signal 404 is in the second state (the low state). The difference between Vg2 and Vs is the gate-to-source voltage Vgs whilst the control signal 404 is in the second state (the low state). In further embodiments the gate driving system 400 may be configured to control Vgs to follow the desired waveforms, for example, constant difference between Vg and Vs; or other shapes to optimize the balance between Rds_on and EMI, etc.

It can be observed that embodiments of the gate driving system 400 may provide an adaptive MOSFET drive method to optimize MOSFET driving and keep Vgs at its optimized value to balance efficiency and EMI performance.

Embodiments of the present disclosure enable the gate voltage Vg to follow the source voltage Vs during the conduction period of the MOSFET 402 to ensure that the gate-to-source voltage Vgs remains at an optimized value. This helps balance efficiency and EMI to a pre-designed balance value, improving overall performance.

During the turn of period of the MOSFET 402, the gate voltage Vg may also track the source voltage Vs, thereby keeping the gate-to-source voltage Vgs stable, and at a lower level to ensure efficient turn-off.

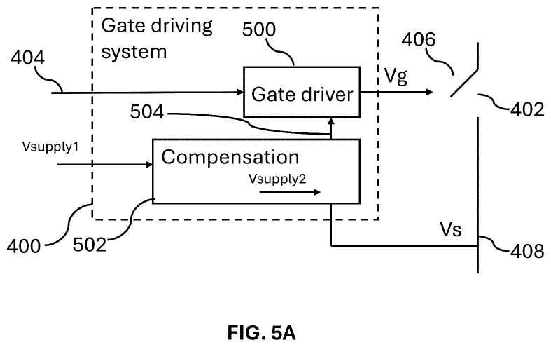

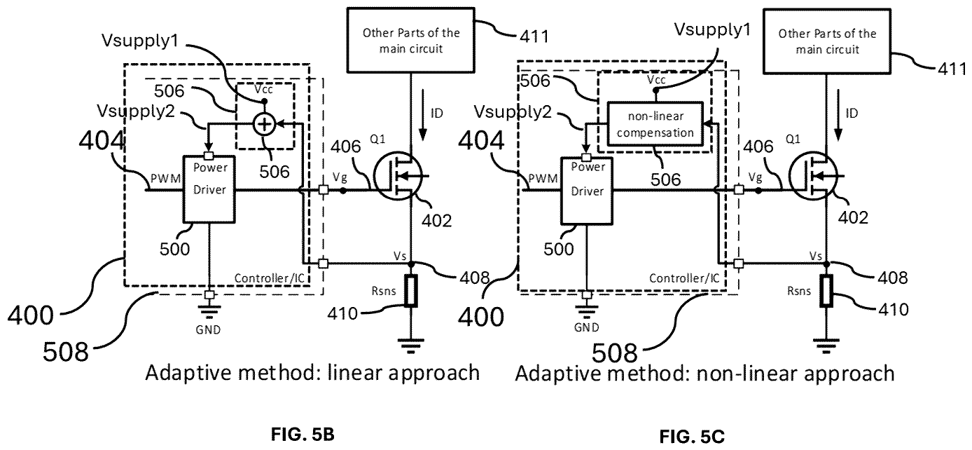

FIG. 5A is a schematic of a specific embodiment of the gate driving system 400 of FIG. 4A in accordance with a third embodiment of the present disclosure.

In the present embodiment, the gate driving system 400 comprises a gate driver circuit 500 configured to receive the control signal 404 and provide the gate drive voltage signal Vg to the gate terminal 406 of the switch 402 to drive the switching operation of the switch 402. In a further embodiment, the switch 402 may be a MOSFET, for example as described in relation to FIG. 4B. Furthermore, the switch 402 may be coupled to the sense resistor 410 and/or additional circuitry 411 as described in relation to FIG. 4B.

The gate driving system 400 further comprises a compensation circuit 502 that is configured to detect the voltage Vs and to provide an adjustment signal 504 to the gate driver circuit 500. The adjustment signal 504 is dependent on the detected voltage Vs. During operation, the gate driver circuit 500 adjusts the gate drive voltage signal Vg based on the adjustment signal 504. In a specific embodiment, the compensation circuit 502 may be configured to receive a supply voltage Vsupply1 and to generate an adjusted supply voltage Vsupply2 that is dependent on the voltage Vs and the received supply voltage Vsupply1, as detected.

The adjustment signal 504 may be dependent on the adjusted supply voltage Vsupply2 and in a specific embodiment, the adjustment signal 504 may be the adjusted supply voltage Vsupply2.

In a specific embodiment, the gate drive voltage Vg1 may be provided using the adjusted supply voltage Vsupply2, and may, for example, be equal to the adjusted supply voltage Vsupply2. Alternatively, or additionally, the gate drive voltage Vg2 may be provided using the adjusted supply voltage Vsupply2, and may, for example, be equal to the adjusted supply voltage Vsupply2. It is worth noting that the addition circuit is only one of many forms of compensation circuits.

FIG. 5B is a schematic of the gate driving system 400 having a specific embodiment of the compensation circuit 502, in accordance with a fourth embodiment of the present disclosure. In the present embodiment, the compensation circuit 502 comprises an addition circuit 506 that is configured to generate the adjusted supply voltage Vsupply2 by adding the supply voltage Vsupply1 and the voltage Vs.

FIG. 5C is a schematic of the gate driving system 400 having a specific embodiment of the compensation circuit 502, in accordance with a fifth embodiment of the present disclosure. In the present embodiment, the addition circuit 506 is configured to successively generated the adjusted supply voltage Vsupply2 at discrete time intervals during operation.

The embodiments presented in FIG. 5B and FIG. 5C represent two approaches to compensate Vg because of the change of Vs. Specifically, the embodiment presented in FIG. 5B is a linear approach and the embodiment presented in FIG. 5C is a non-linear approach.

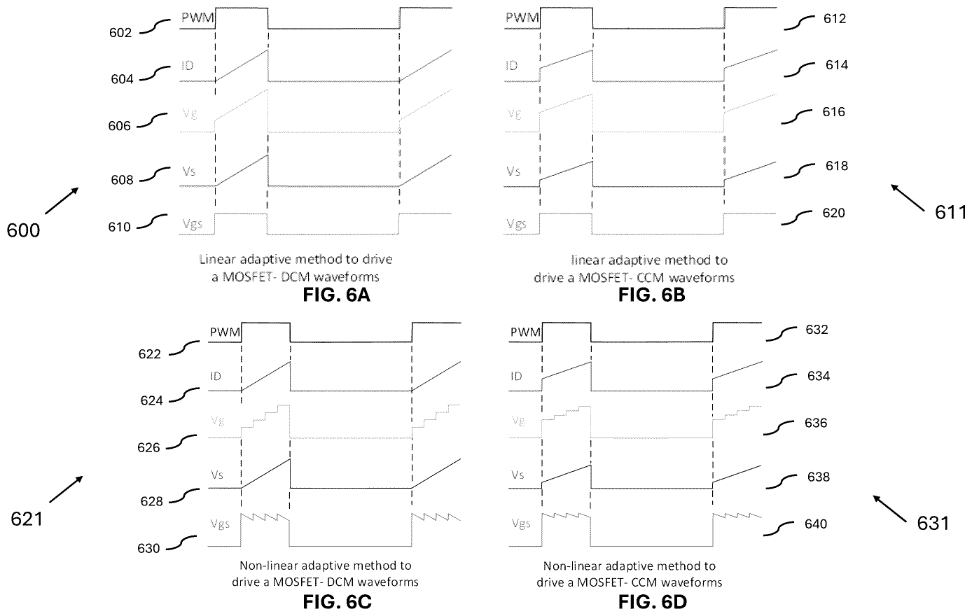

FIG. 6A is a graph 600 showing waveforms associated with the operation of a practical implementation of the gate driving system 400 of FIG. 5B, which is the linear adaptive MOSFET drive approach using DCM. In the present example, the MOSFET 402 is part of a boost converter.

There is shown: the control signal 404, denoted as “PWM” (a trace 602), the drain current ID (a trace 604), the gate drive voltage signal Vg (a trace 606), the source voltage Vs (a trace 608) and the gate-to-source voltage Vgs (a trace 610).

FIG. 6B is a graph 611 showing waveforms associated with the operation of a practical implementation of the gate driving system 400 of FIG. 5B, which is the linear adaptive MOSFET drive approach using CCM. In the present example, the MOSFET 402 is part of a boost converter.

There is shown: the control signal 404, denoted as “PWM” (a trace 612), the drain current ID (a trace 614), the gate drive voltage signal Vg (a trace 616), the source voltage Vs (a trace 618) and the gate-to-source voltage Vgs (a trace 620).

FIG. 6C is a graph 621 showing waveforms associated with the operation of a practical implementation of the gate driving system 400 of FIG. 5B, which is the non-linear adaptive MOSFET drive approach using DCM. In the present example, the MOSFET 402 is part of a boost converter.

There is shown: the control signal 404, denoted as “PWM” (a trace 622), the drain current ID (a trace 624), the gate drive voltage signal Vg (a trace 626), the source voltage Vs (a trace 628) and the gate-to-source voltage Vgs (a trace 630).

FIG. 6D is a graph 631 showing waveforms associated with the operation of a practical implementation of the gate driving system 400 of FIG. 5B, which is the non-linear adaptive MOSFET drive approach using CCM. In the present example, the MOSFET 402 is part of a boost converter.

There is shown: the control signal 404, denoted as “PWM” (a trace 632), the drain current ID (a trace 634), the gate drive voltage signal Vg (a trace 636), the source voltage Vs (a trace 638) and the gate-to-source voltage Vgs (a trace 640).

In the present examples, the waveforms are represented as voltages varying with time. The drain current ID may alternatively be referred to as the “drive current”.

The embodiment of the gate driving system 400 presented in FIG. 5B uses the linear compensation method. In the present embodiment, the linear method is implemented using analog methods, for example, as provided by an analog implementation of the addition circuit 506. Further embodiments may be implemented digitally, for example, by using a digital addition circuit.

In a specific embodiment, the voltage level of vg will be the voltage level on the power pin of the gate driver circuit 500.

The gate driving system 400 may be implemented as part of a controller 508 of a power converter, with the power converter being a boost converter in the present example. As the controller 508

samples the Vs voltage for current sensing or protection purposes, it can use this existing Vs voltage information to dynamically adjust the Vg voltage level in real time to realize Vg=V(gs_desired)+Vs when referred to GND. V(gs_desired) is the target gate-to-source voltage Vgs when the switching operation is optimised.

As the gate driving system 400 may be implemented as part of the controller 508, there can be a reduction in cost and design size when compared to an embodiment providing the gate driving system 400 using external circuitry.

FIG. 6A and FIG. 6B shows the waveforms of the adaptive MOSFET drive method. As shown in FIG. 6A and FIG. 6B, the gate-to-source voltage consistently remains near an optimised value despite fluctuations in the source voltage Vs due to changes in the current ID. Embodiments of the present disclosure using the linear as provided by the embodiment of FIG. 5B can achieve a performance similar to the isolated drive method of FIG. 2B, but without the need for an additional isolated driver, thereby making it much easier to integrate into a chip.

The embodiment of the gate driving system 400 presented in FIG. 5C uses the non-linear compensation method. In the present embodiment, the non-linear method is implemented using digital methods, for example, as provided by a digital implementation of the addition circuit 506. Further embodiments may be implemented using analog circuitry, for example, by using an analog addition circuit.

Unlike the linear method as provided by FIG. 5B, which may compensate in real time, the non-linear method as provided by FIG. 5C compensates in N steps, where N is an integer greater than or equal to two. In operation, the addition circuit 506 successively generates the adjusted supply voltage Vsupply2 at discrete time intervals. This results in the stepped profile of the gate drive voltage signal Vg as shown by the traces 626, 636. In the example waveforms of FIG. 6C and FIG. 6D, N is equal to four.

The non-linear approach of FIG. 5C may be easier to implement digitally than using analog circuitry, and may result in reduced chip die size and cost when compared to the linear method of FIG. 5B.

It will be appreciated that as N increases, the compensation effect becomes closer to that of the linear approach, but this also requires more computational resources. Conversely, a smaller N results in less effective compensation compared to the linear approach but consumes fewer computational resources. This is a trade-off and in a specific embodiment, N may be set as an adjustable parameter, thereby enabling users to select an appropriate value based on their design requirements and the desired balance between performance and calculation resource.

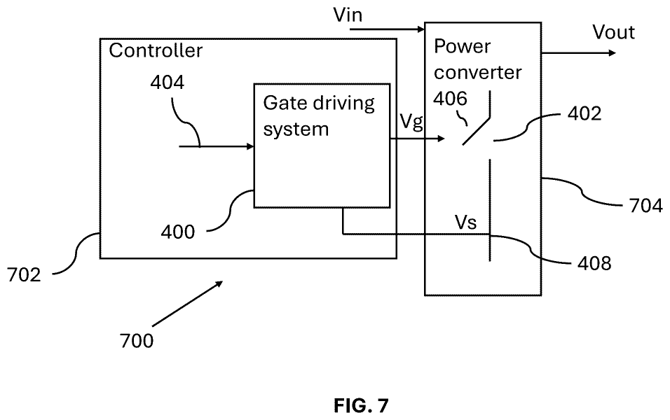

FIG. 7 is a schematic of an apparatus 700 in accordance with a sixth embodiment of the present disclosure. The apparatus 700 comprises the controller 702 for a power converter 704. The power converter 704 is a switching converter that comprises one or more switches. During operation the power converter 704 receives an input voltage Vin and generates an output voltage Vout. The power converter 704 may, for example be a buck converter, a boost converter or a buck boost converter. The controller 702 may be configured to provide a discontinuous conduction mode (DCM) or a continuous conduction mode (CCM) for the power converter 704.

The controller 702 comprises the gate driving system 400, which may be implemented using any of the gate driving system 400 embodiments described herein. In the present embodiment, the switch 402 is one of the power switches of the power converter 704 and may be implemented using any of the switch 402 embodiments as described herein. The gate driving system 400 and the switch 402 function substantially as described previously.

It will be appreciated that in further embodiments, the power converter 704 may comprise two or more power switches, with the gate driving system 400 being configured to drive the switching operation of each of the additional power switches as described for the switch 402, in accordance with the understanding of the skilled person. Specifically, for each of the additional power switches, the gate driving system 400 may be configured to provide a gate drive voltage signal to a gate terminal of the power switch to drive the switching operation of the power switch, detect a voltage at a terminal of the power switch (for example, the source voltage of the power switch at its source terminal), and adjust the gate drive voltage signal based on the voltage, as detected.

Embodiments of the present disclosure provided a novel adaptive method for driving a MOSFET that addresses the limitations of previous approaches. This method provides a cost-effective solution to compensate for the reduction in the gate-to-source voltage Vgs caused by an increase in MOSFET current, thereby avoiding the need for overdesign to account for worst-case scenarios, thereby optimizing the R_{dson} and operational efficiency during the conduction period.

Embodiments of the present disclosure may strike an optimal balance between the known non-isolated method presented in FIG. 2A and the known isolated method presented in FIG. 2B. Embodiments of the present disclosure may offer a low-cost solution to the problem of increased R_{dson} due to rising current, thereby enhancing efficiency, power density, and reliability. Embodiments of the present disclosure provide a novel adaptive method for driving the MOSFET that uses a gate voltage V_{g} that dynamically tracks the source voltage (Vₛ) to compensate for variations in Vₛ under different currents. This approach may ensure that V_{gs} consistently stays close to its optimized design value, thereby enabling high-efficiency operation of the MOSFET without increasing cost or design size.

Embodiments of the present disclosure provide an adaptive drive control for power switches (such as Silicon MOSFETs, SiC, GaN, IGBT, etc.) that optimizes their performance without

increasing costs and size. It enhances Silicon-MOSFET/SiC/GaN/IGBT efficiency, reduces heat generation, and lowers the cost and size requirements for heat sinks, thereby increasing the power density of the power supply.

Embodiments of the present disclosure do not need to be limited to any specific type of MOSFET and may, for example, be applied to MOSFETs such as silicon MOSFET, SiC MOSFET, or GaN MOSFET. Embodiments of the present disclosure may also use IGBT transistors.

Embodiments of the present disclosure may provide a novel adaptive gate driver method for MOSFETs, specifically aimed at optimizing gate voltage and enhancing the overall performance on efficiency and EMI without incurring additional costs.

In summary, the proposed adaptive drive method maintains the V_{gs} of the MOSFET close to its optimized design value, thereby achieving a well-balanced R_{dson}, in addition to improvements in conduction loss, EMI performance, and switching loss. It eliminates the need for an additional isolated MOSFET driver and may be easily integrated into an integrated circuit (IC) either by linear method or non-linear method, further reducing costs and increasing power density.

Various improvements and modifications may be made to the above without departing from the scope of the disclosure.

1. A gate driving system for driving a switching operation of a first switch, the gate driving system being configured to:
receive a control signal;
provide a gate drive voltage signal to a gate terminal of the first switch to drive the switching operation of the first switch;
detect a first voltage at a first terminal of the first switch; and
adjust the gate drive voltage signal based on the first voltage, as detected.

2. The gate driving system of claim 1, wherein the gate driving system is configured to:
provide the gate drive voltage signal having a first gate drive voltage when the control signal is in a first state; and
provide the gate drive voltage signal having a second gate drive voltage when the control signal is in a second state.

3. The gate driving system of claim 2, wherein the gate driving system is configured to:
adjust the first gate drive voltage using the first voltage as detected, to maintain a substantially constant difference between the first gate drive voltage and the first voltage whilst the control signal is in the first state; and/or
adjust the second gate drive voltage using the first voltage as detected, to maintain a substantially constant difference between the second gate drive voltage and the first voltage whilst the control signal is in the second state.

4. The gate driving system of claim 1, wherein the first switch is a metal-oxide-semiconductor field-effect transistor (MOSFET).

5. The gate driving system of claim 4, wherein the MOSFET is a silicon MOSFET, a silicon carbide MOSFET or a gallium nitride MOSFET.

6. The gate driving system of claim 4, wherein the MOSFET is an N-channel enhancement-mode MOSFET.

7. The gate driving system of claim 4, wherein the first voltage is a source voltage and the first terminal is a source terminal.

8. The gate driving system of claim 1, wherein the first switch is coupled to a sense resistor at the first terminal and/or the first switch is coupled to additional circuitry at a second terminal.

9. The gate driving system of claim 1, wherein the control signal is a pulse width modulation (PWM) signal.

10. The gate driving system of claim 1, further comprising:
a gate driver circuit configured to:
receive the control signal; and
provide the gate drive voltage signal to the gate terminal of the first switch to drive the switching operation of the first switch; and
a compensation circuit configured to:
detect the first voltage at the first terminal of the first switch; and
provide an adjustment signal that is dependent on the detected first voltage to the gate driver circuit;
wherein the gate driver circuit is configured to adjust the gate drive voltage signal based on the received adjustment signal.

11. The gate driving system of claim 10, wherein the compensation circuit is configured to:
receive a supply voltage; and
generate an adjusted supply voltage based on the detected first voltage, the adjustment signal being dependent on the adjusted supply voltage.

12. The gate driving system of claim 11, wherein the adjustment signal is the adjusted supply voltage.

13. The gate driving system of claim 12, wherein the gate driving system is configured to:
provide the gate drive voltage signal having a first gate drive voltage when the control signal is in a first state;
provide the gate drive voltage signal having a second gate drive voltage when the control signal is in a second state; and
providing
the first gate drive voltage using adjusted supply voltage, thereby adjusting gate drive voltage signal based on the first voltage; and/or
the second gate drive voltage using adjusted supply voltage, thereby adjusting gate drive voltage signal based on the first voltage.

14. The gate driving system of claim 11, wherein the compensation circuit comprises an addition circuit configured to generate the adjusted supply voltage by adding the supply voltage and the detected first voltage.

15. The gate driving system of claim 11, wherein the addition circuit is configured to successively generate the adjusted supply voltage at discrete time intervals during operation.

16. An apparatus comprising:
a controller for controlling a power converter for receiving an input voltage and generating an output voltage, the power converter comprising one or more power switches;
wherein the controller comprises a gate driving system for driving a switching operation of each of the one or more power switches, the gate driving system being configured to:
receive a control signal; and,
for each of the one or more power switches:
provide a gate drive voltage signal to a gate terminal of the power switch to drive the switching operation of the power switch;
detect a first voltage at a first terminal of the power switch; and
adjust the gate drive voltage signal based on the first voltage, as detected.

17. The apparatus of claim 16, further comprising the power converter.

18. The apparatus of claim 16, wherein the controller is configured to provide a discontinuous conduction mode (DCM) or a continuous conduction mode (CCM) for the power converter.

19. The apparatus of claim 16, wherein the power converter is a buck converter, a boost converter or a buck-boost converter.

20. A method of driving a switching operation of a first switch using a gate driving system, the method comprising:
receiving a control signal;
providing a gate drive voltage signal to a gate terminal of the first switch to drive the switching operation of the first switch;
detecting a first voltage at a first terminal of the first switch; and
adjusting the gate drive voltage signal based on the first voltage, as detected.
